(19) United States
(12) Patent Application Publication
(10) Pub. No.: US 2022/0195619 A1
(43) Pub. Date: Jun. 23, 2022

(54) METHOD FOR MAKING ELECTRONIC BLACKBODY STRUCTURE AND ELECTRONIC BLACKBODY STRUCTURE

(71) Applicants: Tsinghua University, Beijing (CN); HON HAI PRECISION INDUSTRY CO., LTD., New Taipei (TW)

(72) Inventors: KE ZHANG, Beijing (CN); GUO CHEN, Beijing (CN); PENG LIU, Beijing (CN); KAI-LI JIANG, Beijing (CN); SHOU-SHAN FAN, Beijing (CN)

(21) Appl. No.: 17/225,713

(22) Filed: Apr. 8, 2021

(30) Foreign Application Priority Data
Dec. 17, 2020 (CN) 202011503855.8

(51) Int. Cl. C30B 25/18; G01J 5/52; H05B 3/14

(52) U.S. Cl. CPC C30B 25/18; B82Y 30/00; H05B 3/145; G01J 5/522

(57) ABSTRACT

A method for making an electronic blackbody structure is provided. The method comprises: providing a growing substrate; growing a carbon nanotube array on the growing substrate, the carbon nanotube array including a top surface and a bottom surface, the bottom surface being connected to the growing substrate; and separating the carbon nanotube array from the growing substrate, exposing the bottom surface of the carbon nanotube array, and the bottom surface of the carbon nanotube array is used to absorb electrons. An electronic blackbody structure is further provided.

### CROSS-REFERENCE TO RELATED APPLICATIONS

This application claims all benefits accruing under 35 U.S.C. § 119 from China Patent Application No. 202011503855.8, filed on Dec. 17, 2020, in the China Intellectual Property Office, the contents of which are hereby incorporated by reference. The application is also related to copending applications entitled, “ELECTRON BEAM DETECTION DEVICE AND METHOD FOR DETECTING ELECTRON BEAM USING THE SAME,” filed ______ (Atty. Docket No. US82853); “ELECTRONIC BLACKBODY CAVITY AND SECONDARY ELECTRON DETECTION DEVICE USING THE SAME,” filed ______ (Atty. Docket No. US82854); “SECONDARY ELECTRON PROBE AND SECONDARY ELECTRON DETECTOR,” filed ______ (Atty. Docket No. US82855); “ELECTRONIC BLACKBODY MATERIAL AND ELECTRON DETECTOR”, filed ______ (Atty. Docket No. US82857); “DEVICE AND METHOD FOR MEASURING ELECTRON BEAM,” filed ______ (Atty. Docket No. US83296).

### FIELD

The present disclosure relates to a method for making electronic blackbody structure and an electronic blackbody structure.

### BACKGROUND

Electron-absorbing components are often required to absorb electrons in a microelectronics technology field. Metals are usually used to absorb electrons. However, when the metals are used to absorb electrons, a large number of electrons are reflected or transmitted on a surface of the metals and cannot be absorbed by the metals. Therefore, an absorption efficiency of electrons is low.

At present, there is no material that can absorb nearly 100% of electrons; this material can also be called an electronic blackbody. Therefore, it is a great significance to design an electronic blackbody structure with an absorption rate of almost 100%.

### BRIEF DESCRIPTION OF THE DRAWINGS

Implementations of the present technology will now be described, by way of example only, with reference to the attached figures, wherein:

FIG. 1 is a flow chart of a method for making an electronic blackbody structure according to one embodiment of the present invention.

FIG. 2 is a structure schematic diagram of a carbon nanotube array according to one embodiment.

FIG. 3 is a schematic flow chart of a method for separating a carbon nanotube array and a growing substrate provided by one embodiment of the present invention.

FIG. 4 is an electron absorption rate comparison diagram between the electronic blackbody structure provided by one embodiment of the present invention and a directly grown carbon nanotube array.

FIG. 5 is a structure schematic diagram of one embodiment of an electronic blackbody structure.

FIG. 6 is an electron absorption rate comparison diagram between the electronic blackbody structure provided by one embodiment of the present invention and other materials.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “include, but not necessarily limited to”; it specifically indicates open-ended inclusion or membership in the so-described combination, group, series, and the like.

A method for preparing an electronic blackbody structure is provided by the present invention. And the electronic blackbody structure obtained by the method will be further described in detail below with reference to the accompanying drawings and specific embodiments. The electronic blackbody structure refers to a structure in which the absorption rate of electrons is almost 100%.

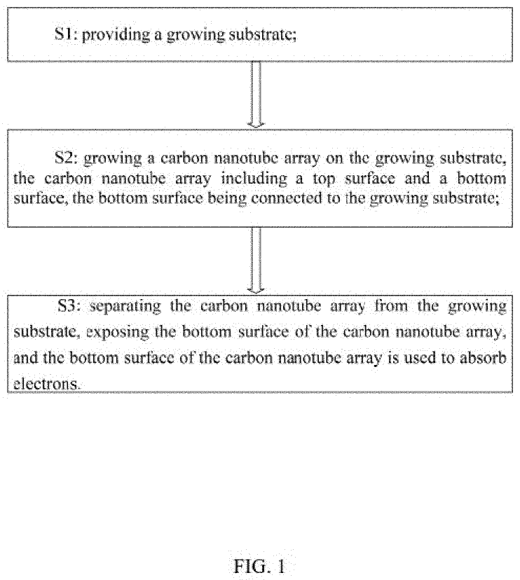

Referring to FIG. 1, a method for making the electronic blackbody structure according to one embodiment is provided. The method comprises following steps:

S1: providing a growing substrate;

S2: growing a carbon nanotube array on the growing substrate, the carbon nanotube array including a top surface and a bottom surface, the bottom surface being connected to the growing substrate; and

S3: separating the carbon nanotube array from the growing substrate, exposing the bottom surface of the carbon nanotube array, and the bottom surface of the carbon nanotube array is used to absorb electrons.

In step S1, a material of the growing substrate can be a substrate suitable for growing carbon nanotube arrays, such as, P-type silicon, N-type silicon, or silicon oxide.

In step S2, the method for growing the carbon nanotube array is not limited, and the carbon nanotube array can be grown by a chemical vapor deposition method. In this embodiment, the method for growing the carbon nanotube array comprises:

providing a flat and smooth growing substrate, the growing substrate can be a p-type silicon substrate, an n-type silicon substrate or an intrinsic silicon substrate. In this embodiment, the growing substrate is a p-type silicon substrate, which has a diameter of 8 inches and a thickness of 500 microns. A metal catalyst is formed by an electron beam evaporation method, a thermal deposition method or a sputtering method. A thickness of the growing substrate is several nanometers to several hundred nanometers. A material of the metal catalyst layer can be iron (Fe), cobalt (Co), nickel (Ni) or alloys of them. In this embodiment, the material of the metal catalyst is iron, and a thickness of the metal catalyst layer is about 5 nm;

the growing substrate with the metal catalyst layer is annealed in air at a temperature ranging from 300 to 400° C. for about 10 hours. In the presence of protective gas, heating in a reaction furnace for a period of time to reach a temperature. The temperature is in a range from 500° C. to 700° C., preferably 650° C.;

introducing 30 sccm carbon source gas and 300 sccm protective gas (such as argon) for 5-30 minutes to grow the carbon nanotube array.

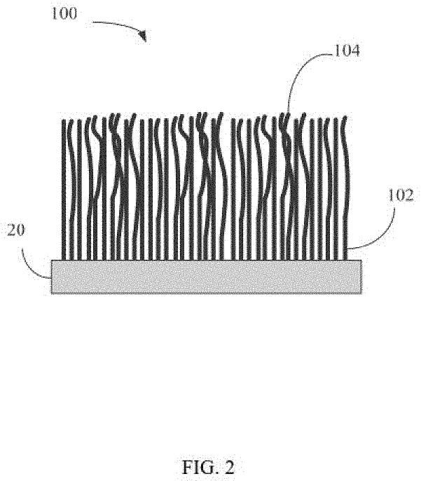

Referring to FIG. 2, a carbon nanotube array 10 is provided by the above method. The carbon nanotube array 10 comprises a plurality of carbon nanotubes 100 substantially parallel to each other and perpendicular to a growing substrate 20. The carbon nanotube array 10 prepared by the chemical vapor deposition method is basically perpendicular to the growing substrate 20 when it is initially grown from the surface of the catalyst layer. As a length of the carbon nanotube 100 increases, part of the carbon nanotube 100 begins to bend, therefore, the carbon nanotubes 100 on a bottom surface 102 of the carbon nanotube array 10 in contact with the growing substrate 20 is substantially perpendicular to the growing substrate 20, while the carbon nanotubes 100 on a top surface 104 of the carbon nanotube array 10 far away from the growing substrate 20 are curved.

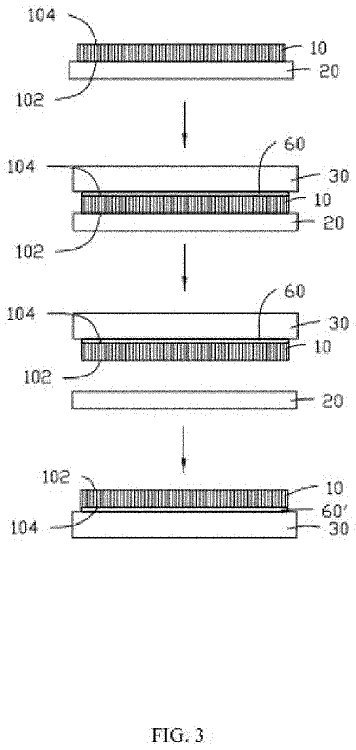

In step S3, the method of separating the carbon nanotube array and the growing substrate to expose the bottom surface of the carbon nanotube array is not limited, as long as the carbon nanotube array and the growing substrate can be separated without damaging the carbon nanotube array. In this embodiment, referring to FIG. 3, the method of separating the carbon nanotube array and the growing substrate to expose the bottom surface of the carbon nanotube array comprises the following steps:

S31: providing a substitute substrate 30, placing the substitute substrate 30 on the top surface 104 of the carbon nanotube array 10;

S32: sandwiching a liquid medium 60 between a surface of the substitute substrate 30 and the top surface 104 of the carbon nanotube array 10;

S33: solidifying the liquid medium 60 between the substitute substrate 30 and the carbon nanotube array 10 into a solid medium 60′; and

S34: moving the substitute substrate 30 and the growing substrate 20 away from each other, thereby separating the carbon nanotube array 10 from the growing substrate 20 and is transferred to the substitute substrate 30, and the bottom surface 104 of the carbon nanotube array 10 is connected with a surface of the substitute substrate 30, and the bottom surface 102 of the carbon nanotube array 10 is exposed out.

In step S31, the substitute substrate 30 can be a soft, elastic, or rigid solid substrate. The substitute substrate 30 has a surface to accept the carbon nanotube array 10 thereon. The surface of the substitute substrate 30 can be flat when the carbon nanotube array 10 is grown on a flat growing surface of the growing substrate 20. During transferring of the carbon nanotube array 10 from the growing substrate 20 to the substitute substrate 30, the state of the carbon nanotube array 10 is kept unchanged. In one embodiment,

In step S32, the liquid medium 60 can be in a shape of fine droplets, mist, or film. The liquid medium 60 can spread on the entire top surface 104. The liquid medium 60 can be water and/or organic solvents with small molecular weights that are volatile at room temperature or easily evaporated by heating. The organic solvent can be selected from ethanol, methanol, and acetone. The liquid medium 60 can have a poor wettability for carbon nanotubes. Thus, when a small amount of liquid medium 60 is on the top surface 104 of the carbon nanotube array 10, it cannot infiltrate inside the carbon nanotube array 10 and will not affect the state of the carbon nanotube array 10. A diameter of the liquid medium droplet and a thickness of the liquid medium film can be in a range from about 10 nanometers to about 300 microns. The substitute substrate 30 and the top surface 104 of the carbon nanotube array 10 are both in contact with the liquid medium 60.

In one embodiment, the liquid medium 60 is applied on the surface of the substitute substrate 30, and then contacting the top surface 104 of the carbon nanotube array 10 with the liquid medium 60 located on the surface of substitute substrate 30. The substitute substrate 30 may apply a pressing force as small as possible to the carbon nanotube array 10. The pressing force can satisfy 0<f<2N/cm². The pressing force does not press the carbon nanotubes down or vary the length direction of the carbon nanotubes in the carbon nanotube array 10. The carbon nanotubes in the carbon nanotube array 10 between the substitute substrate 30 and the growing substrate 20 are always substantially perpendicular to the growing surface of the growing substrate 20.

In step S33, a temperature of the liquid medium 60 can be decreased to be below the freezing point of the liquid medium 60. After the liquid medium 60 is solidified, the substitute substrate 30 and the carbon nanotube array 10 can be firmly bonded together by the solid medium 60′ therebetween.

The carbon nanotube array 10 is separated from the growing substrate 20 by being combined with the replacement substrate 30. Preferably, all the carbon nanotubes in the carbon nanotube array 10 are separated from the growing substrate 20 at the same time, that is, the moving direction of at least one of the substitute substrate 30 and the growing substrate 20 is perpendicular to the carbon nanotubes of the carbon nanotube array 10. When the substitute substrate 30 and the growing substrate 20 both move, their moving direction is perpendicular to the carbon nanotube growing direction of the carbon nanotube array 10.

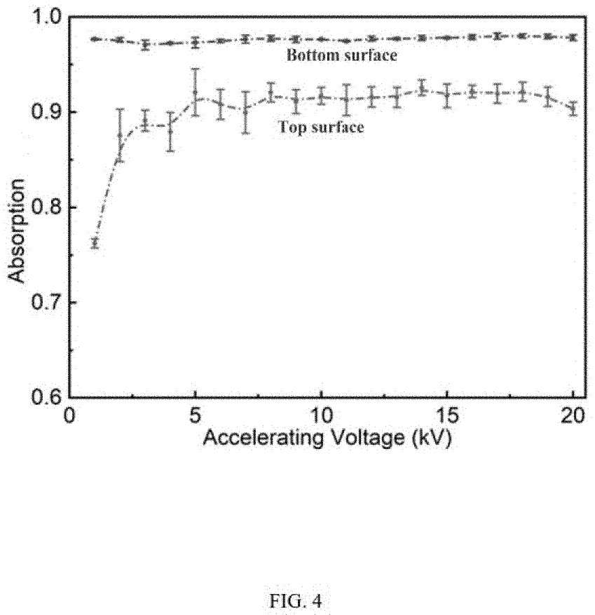

After the carbon nanotube array is transferred to the substitute substrate, the top surface of the carbon nanotube array is arranged on the surface of the substitute substrate, and the bottom surface of the carbon nanotube array is far away from the substitute substrate and is exposed as an electron absorption surface with an electronic blackbody structure. Since on the bottom surface of the carbon nanotube array, the carbon nanotubes are neatly arranged and substantially perpendicular to the growing substrate, the bottom surface of the carbon nanotube array used as the absorption surface of the electronic blackbody has a higher electron absorption rate. Referring to FIG. 4, compared with the top surface of the carbon nanotube array, the electronic blackbody structure provided by the embodiment of the present invention uses the bottom surface of the carbon nanotube array as an electron absorption surface, which has a higher electron absorption rate.

An electronic blackbody structure is prepared by the above method for making an electronic blackbody structure. The electronic blackbody structure comprises a supporting substrate and a carbon nanotube structure, and the carbon nanotube structure comprises a plurality of carbon nanotubes. The plurality of carbon nanotubes are substantially parallel to each other and perpendicular to the supporting substrate. The carbon nanotube structure can be obtained by turning over a carbon nanotube array. The carbon nanotube array is directly grown on a growing substrate. The carbon nanotube array comprises a top surface and a bottom surface. The bottom surface of the carbon nanotube array is connected to the growing substrate. After the carbon nanotube array is separated from the growing substrate, the shape of the carbon nanotube array is maintained and transferred to the supporting substrate. The top surface of the carbon nanotube array is connected to the supporting substrate, thereby forming the carbon nanotube structure.

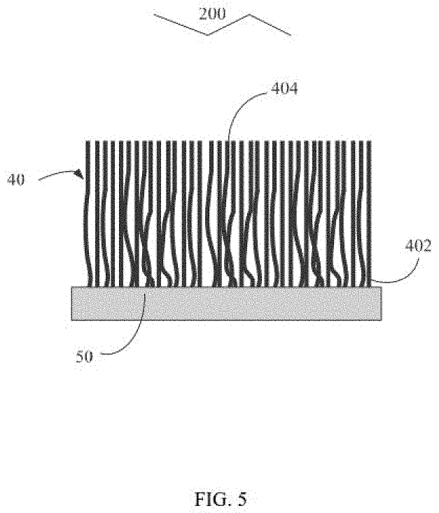

Referring to FIG. 5, the electronic blackbody structure 200 comprises a supporting substrate 50 and a carbon nanotube structure 40. The carbon nanotube structure 40 comprises a first surface 402 and a second surface 404, the first surface 402 is in contact with the supporting substrate 50, and the second surface 404 is away from the supporting substrate 50. A dielectric layer (not shown) can be further included between the carbon nanotube structure 40 and the supporting substrate 50, and the first surface 402 of the carbon nanotube structure 40 is inserted into the dielectric layer. The carbon nanotube structure 40 comprises a plurality of carbon nanotubes. The plurality of carbon nanotubes are not absolutely straight lines. Portions of the carbon nanotubes close to the second surface 404 are basically linear, and are parallel with each other. Portions of the carbon nanotubes close to the first surface 402 can be linear, curved, or randomly distributed.

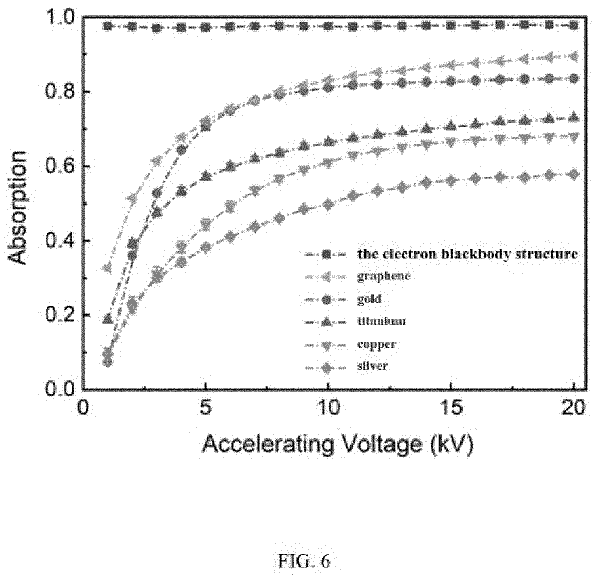

Referring to FIG. 6, compared with metal materials and graphite, the electronic blackbody structure provided the present invention can absorb almost 100% of electrons.

The electronic blackbody structure provided by the present invention has a simple structure, and the absorption rate of electrons can reach almost 100%. It has a wide range of application prospects, and the preparation method of the electronic blackbody structure is simple and easy to operate.

It is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described may be removed, others may be added, and the sequence of steps may be altered. The description and the claims drawn to a method may include some indication in reference to certain steps. However, the indication used is only to be viewed for identification purposes and not as a suggestion as to an order for the steps.

What is claimed is:

1. A method for making an electronic blackbody structure comprising:
providing a growing substrate;
growing a carbon nanotube array on the growing substrate, the carbon nanotube array comprising a top surface and a bottom surface, the bottom surface is connected to the growing substrate; and
separating the carbon nanotube array from the growing substrate, exposing the bottom surface of the carbon nanotube array, and the bottom surface of the carbon nanotube array is used to absorb electrons.

2. The method of claim 1, wherein the carbon nanotube array is grown via a chemical vapor deposition method.

3. The method of claim 1, wherein the carbon nanotube array comprises a plurality of carbon nanotubes, part of the plurality of on the bottom surface is perpendicular to the growing substrate.

4. The method of claim 3, wherein part of the plurality of carbon nanotubes on the top surface is curved.

5. The method of claim 1, wherein the method of separating the carbon nanotube array and the growing substrate comprises:
S31: providing a substitute substrate, placing the substitute substrate on the top surface of the carbon nanotube array;
S32: sandwiching a liquid medium between a surface of the substitute substrate and the top surface of the carbon nanotube array;
S33: solidifying the liquid medium between the substitute substrate and the carbon nanotube array into a solid medium; and
S34: moving the substitute substrate and the growing substrate away from each other, to separate the carbon nanotube array from the growing substrate.

6. The method of claim 5, wherein after the carbon nanotube array is transferred to the substitute substrate, and the bottom surface of the carbon nanotube array is connected with a surface of the substitute substrate, and the bottom surface of the carbon nanotube array is exposed out.

7. The method of claim 6, wherein the bottom surface of the carbon nanotube array is configured to absorb electrons.

8. The method of claim 1, wherein in step S32, the substitute substrate apply a pressing force to the carbon nanotube array, and the pressing force is less than 2N/cm².

9. An electronic blackbody structure, comprising:
a supporting substrate and a carbon nanotube structure, wherein the carbon nanotube structure comprises a plurality of carbon nanotubes, the carbon nanotube structure is obtained by turning over a carbon nanotube array.

10. The electronic blackbody structure of claim 9, wherein the carbon nanotube array is directly grown on a growing substrate.

11. The electronic blackbody structure of claim 9, wherein the carbon nanotube array comprises a top surface and a bottom surface, the top surface of the carbon nanotube array is connected to the supporting substrate, the bottom surface of the carbon nanotube array is configured to absorb electrons.

12. An electronic blackbody structure, comprising:
a supporting substrate and a carbon nanotube structure, wherein the carbon nanotube structure comprises a first surface and a second surface, the first surface is in contact with the supporting substrate, and the second surface is away from the supporting substrate, the carbon nanotube structure comprises a plurality of carbon nanotubes, portions of the carbon nanotubes close to the second surface are linear and parallel with each other.

13. The electronic blackbody structure of claim 12, wherein the plurality of carbon nanotubes are not straight lines.

14. The electronic blackbody structure of claim 12, wherein portions of the carbon nanotubes close to the first surface are linear, curved, or randomly distributed.
